(19) United States
(12) Patent Application Publication
(10) Pub. No.: US 2021/0335586 A1
(43) Pub. Date: Oct. 28, 2021

(54) METHODS AND APPARATUS FOR CLEANING A SHOWERHEAD

(71) Applicant: APPLIED MATERIALS, INC., Santa Clara, CA (US)

(72) Inventors: Tom H. YU, Campbell, CA (US); Wei Min CHAN, Sunnyvale, CA (US); Peiqi WANG, Campbell, CA (US); Kai WU, Palo Alto, CA (US); Adolph Miller ALLEN, Oakland, CA (US); Kazuya DAITO, Milipitas, CA (US)

(21) Appl. No.: 16/855,496

(22) Filed: Apr. 22, 2020

(51) Int. Cl. H01J 37/32; B08B 5/00; B08B 7/00

(52) U.S. Cl. CPC H01J 37/32853; H01J 37/3244; B08B 2205/00; B08B 7/0071; H01J 2237/3321; B08B 5/00

(57) ABSTRACT

Methods and apparatus for cleaning a showerhead are provided. For example, the methods includes moving a substrate support including a heater disposed therein from a substrate processing position a first distance away from the showerhead to a cleaning position a second distance away from the showerhead, wherein the second distance is less than the first distance; heating the showerhead using the heater disposed in the substrate support to a predetermined temperature; at least one of supplying at least one cleaning gas to the processing chamber to form a plasma or supplying the plasma from a remote plasma source; and providing a predetermined pressure within an inner volume of the processing chamber and maintaining the plasma within the inner volume of the processing chamber while heating the showerhead to the predetermined temperature.

### FIELD

Embodiments of the present disclosure generally relate to a method and apparatus for cleaning a showerhead.

### BACKGROUND

Showerheads used for processing substrates in a processing chamber are known. For example, showerheads can be used in chemical vapor deposition (CVD) chambers for depositing one or more materials on one or more substrates. After performing multiple CVD processes, however, residue of one or more materials that form the substrate can accumulate on a substrate facing surface of the showerhead.

Conventional methods for removing the residue can include replacing the showerhead or configuring the showerhead to include one or more heaters, which can be used to enable sublimation of the residue. Such methods, however, can increase preventive maintenance (PM) time, reduce mean wafers between cleans (MWBC), and/or increase complexity of the processing chamber and/or the showerhead.

Therefore, methods and apparatus for cleaning a showerhead are needed.

### SUMMARY

Methods and apparatus for cleaning a showerhead are provided herein. In some embodiments, for example, a method for cleaning a showerhead includes moving a substrate support including a heater disposed therein from a substrate processing position a first distance away from the showerhead to a cleaning position a second distance away from the showerhead, wherein the second distance is less than the first distance; heating the showerhead using the heater disposed in the substrate support to a predetermined temperature; at least one of supplying at least one cleaning gas to the processing chamber to form a plasma or supplying the plasma from a remote plasma source; and providing a predetermined pressure within an inner volume of the processing chamber and maintaining the plasma within the inner volume of the processing chamber while heating the showerhead to the predetermined temperature.

In accordance with at least some embodiments, a non-transitory computer readable storage medium having stored thereon instructions that when executed by a processor perform a method for cleaning a showerhead disposed in a processing chamber. The method includes moving a substrate support including a heater disposed therein from a substrate processing position a first distance away from the showerhead to a cleaning position a second distance away from the showerhead, wherein the second distance is less than the first distance; heating the showerhead using the heater disposed in the substrate support to a predetermined temperature; at least one of supplying at least one cleaning gas to the processing chamber to form a plasma or supplying the plasma from a remote plasma source; and providing a predetermined pressure within an inner volume of the processing chamber and maintaining the plasma within the inner volume of the processing chamber while heating the showerhead to the predetermined temperature.

In accordance with at least some embodiments, a processing chamber includes a substrate support movable from a substrate processing position a first distance away from a showerhead to a cleaning position a second distance away from the showerhead, wherein the second distance is less than the first distance; at least one of a gas supply that supplies at least one cleaning gas to the processing chamber to form a plasma or a remote plasma source configured to supply the plasma to the processing chamber; a heater disposed in the substrate support to heat the showerhead to a predetermined temperature; a pressure system that provides a predetermined pressure within an inner volume of the processing chamber while the plasma is maintained within the inner volume of the processing chamber and the showerhead is being heated to the predetermined temperature; and a controller configured to control the processing chamber to: move the substrate support including the heater disposed therein from the substrate processing position the first distance away from the showerhead to the cleaning position the second distance away from the showerhead, wherein the second distance is less than the first distance; heat the showerhead using the heater disposed in the substrate support to the predetermined temperature; at least one of supply at least one cleaning gas to the processing chamber to form the plasma or supply the plasma from the remote plasma source; and provide the predetermined pressure within the inner volume of the processing chamber and maintain the plasma within the inner volume of the processing chamber while heating the showerhead to the predetermined temperature.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a partial cross-sectional view of a processing chamber in accordance with at least some embodiments of the present disclosure.

FIG. 2 is a is a flowchart of a method of cleaning a showerhead of FIG. 1, according to at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for cleaning a showerhead are provided herein. The methods and apparatus described herein advantageously reduce or eliminate precursors (e.g., residue) left behind on a gas distribution plate of a showerhead, thus reducing or eliminating contamination of substrates being processed. More particularly, a processing chamber, e.g., CVD processing chamber, includes a substrate support that is configured to position a heater disposed therein to a cleaning position for heating a showerhead to a relatively high temperature to remove (e.g., sublimate) residue, e.g., titanium fluoride (TiFₓ), such as TiF₂, TiF₃, TiF₄, etc., on the showerhead. The methods and apparatus described herein do not require opening the processing chamber (e.g., for showerhead replacement), thus eliminating the need of exposing an interior of the processing chamber to a surrounding environment. Moreover, unlike conventional methods and apparatus that include replacing the showerhead as part of PM, which can require the processing chamber to be down/open for about 24 hours (e.g., extended processing chamber downtime), the methods and apparatus described herein can be used to clean a showerhead in about 12 hours (e.g., decreased processing chamber downtime), thus increasing productivity gain. Furthermore, as the heater is part of the substrate support, there is less complexity in the showerhead, as opposed to a showerhead including a heater.

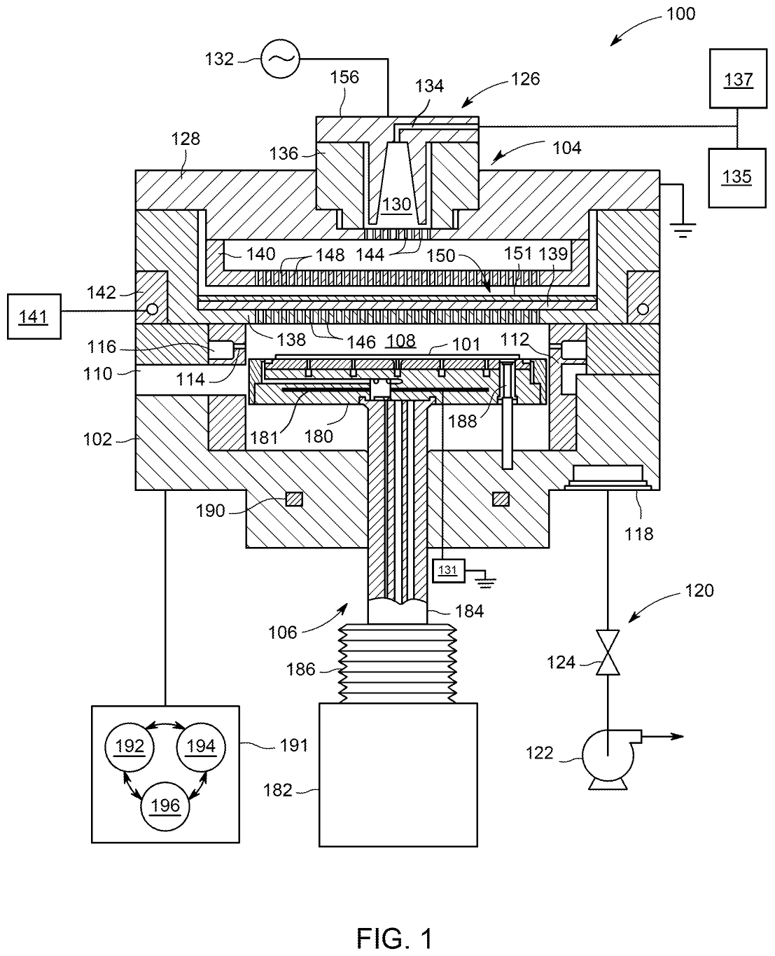

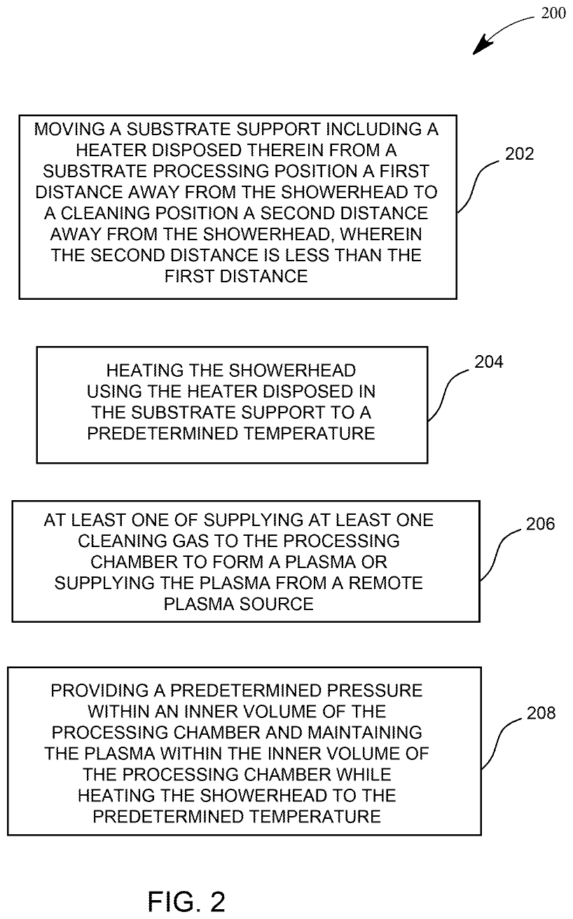

FIG. 1 is a schematic cross-sectional view of a substrate processing chamber 100 including a showerhead 150 adapted for CVD processes, and FIG. 2 is a is a flowchart of a method of cleaning the showerhead 150 of FIG. 1, according to at least some embodiments of the present disclosure. Examples of suitable processing chambers for incorporation of the apparatuses described herein include CVD deposition chambers available from Applied Materials, Inc., of Santa Clara, Calif., such as the CENTURA® iSPRINT® CVD processing chambers. The following processing chamber description is provided for context and exemplary purposes, and should not be interpreted or construed as limiting the scope of the disclosure.

The processing chamber 100 includes a chamber body 102, a lid assembly 104, and a support assembly 106. The lid assembly 104 is positioned at an upper end of the chamber body 102. The support assembly 106 is disclosed in an inner volume 108, defined by the chamber body 102. The chamber body 102 includes a slit valve opening 110 formed in a sidewall thereof. The slit valve opening 110 is selectively opened and closed to allow access to the inner volume 108 by a substrate handling robot (not shown) for substrate transfer.

The chamber body 102 may further include a liner 112 that surrounds the support assembly 106. The liner 112 may be made of a metal such as (Al), a ceramic material, or any other process compatible material. In one or more embodiments, the liner 112 includes one or more apertures 114 and a pumping channel 116 formed therein that is in fluid communication with a vacuum port 118. The apertures 114 provide a flow path for gases into the pumping channel 116. The pumping channel 116 provides an egress for the gases within the processing chamber 100 to vacuum port 118.

A pressure system 120 can be configured to maintain a desired pressure inside the processing chamber 100 and configured to exhaust (e.g., pumping down) the inner volume 108 of the processing chamber 100. For example, in at least some embodiments, the pressure system 120 can include an vacuum port 118 coupled to a pump 122 via a valve 124 for exhausting the inner volume 108 of the processing chamber 100 and maintaining a desired pressure inside the processing chamber 100, e.g., maintaining a relatively high pressure during a cleaning process and a relatively low pressure during substrate processing, or vice versa.

The lid assembly 104 includes at least two stacked components configured to form a plasma volume or cavity therebetween. In one or more embodiments, the lid assembly 104 includes a first electrode (“upper electrode”) 126 disposed vertically above a second electrode (“lower electrode”) 128. The first electrode 126 and the second electrode 128 confine a plasma cavity 130, therebetween. The first electrode 126 is coupled to a power source 132, such as an RF power supply. The second electrode 128 is connected to ground, forming a capacitor between the first electrode 126 and second electrode 128. The first electrode 126 is in fluid communication with a gas inlet 134 that is connected to a gas supply 135, which provides gas, which can be energized to create an active cleaning gas (e.g., ionized plasma or radicals), to the processing chamber 100 via the gas inlet 134 for performing a cleaning process. The first end of the one or more gas inlets 134 opens into the plasma cavity 130.

Alternatively or additionally, the gas supply 135 can be coupled to a remote plasma source (RPS) 137 that is configured to supply the plasma or radicals, depending on the configuration of the RPS, to the plasma cavity 130 of the processing chamber 100.

The lid assembly 104 may also include an isolator ring 136 that electrically isolates the first electrode 126 from the second electrode 128. The isolator ring 136 may be made from aluminum oxide (AlO) or any other insulative, processing compatible, material.

The lid assembly 104 may also include showerhead 150 and, optionally, a blocker plate 140. The showerhead 150 includes a gas distribution plate 138, a backing (gas) plate 139, and a chill plate 151. The second electrode 128, the gas distribution plate 138, the chill plate 151, and the blocker plate 140 may be stacked and disposed on a lid rim 142, which is coupled to the chamber body 102 and can function as a temperature-control ring, as described in more detail below.

The chill plate 151 is configured to regulate a temperature of the gas distribution plate 138 during processing. For example, the chill plate 151 may include one or more temperature control channels (not shown) formed therethrough such that a temperature control fluid may be provided therein to regulate the temperature of the gas distribution plate 138.

In one or more embodiments, the second electrode 128 may include a plurality of gas passages 144 formed beneath the plasma cavity 130 to allow gas from the plasma cavity 130 to flow therethrough. The backing gas plate 139 includes one of more gas passages (not shown) and one or more gas delivery channels ((not shown), thus allowing gas to flow from the one or more gas passages 217 and into the processing region. Similarly, the gas distribution plate 138 includes a plurality of apertures 146 configured to distribute the flow of gases therethrough. The blocker plate 140 may optionally be disposed between the second electrode 128 and the gas distribution plate 138. The blocker plate 140 includes a plurality of apertures 148 to provide a plurality of gas passages from the second electrode 128 to the gas distribution plate 138.

The support assembly 106 may include a support member 180 (e.g., a substrate support). The support member 180 is configured to support the substrate 101 for processing. The support member 180 may be coupled to a lift mechanism 182 through a shaft 184, which extends through a bottom surface of the chamber body 102. The lift mechanism 182 may be flexibly sealed to the chamber body 102 by a bellows 186 that prevents vacuum leakage from around the shaft 184. The lift mechanism 182 allows the support member 180 to be moved vertically within the chamber body 102 between a lower transfer portion and a number of raised process positions. For example, the lift mechanism 182 is configured to position the support member 180 from a substrate processing position a first distance away from the showerhead 150 to a cleaning position a second distance away from the showerhead 150, wherein the second distance is less than the first distance. Additionally, one or more lift pins 188 may be disposed through the support member 180. The one or more lift pins 188 are configured to extend through the support member 180 such that the substrate 101 may be raised off the surface of the support member 180. The one or more lift pins 188 may be active by a lift ring 190.

A heater 181 (e.g., one or more heating electrodes) can be provided in the support assembly 106 and can be configured to heat the support assembly 106 (e.g., to heat the substrate 101 during processing thereof and/or during a cleaning process of the showerhead 150). The heater 181 is coupled to a DC power source 131 to heat the support assembly 106 to a predetermined temperature, e.g., to heat the substrate 101 and/or the showerhead 150.

The processing chamber may also include a controller 191. The controller 191 includes programmable central processing unit (CPU) 192 that is operable with a memory 194 and a mass storage device, an input control unit, and a display unit (not shown), such as power supplies, clocks, cache, input/output (I/O) circuits, and the liner 112, coupled to the various components of the processing system to facilitate control of the substrate processing.

To facilitate control of the processing chamber 100 described above, the CPU 192 may be one of any form of general-purpose computer processor that can be used in an industrial setting, such as a programmable logic controller (PLC), for controlling various chambers and sub-processors. The memory 194 is coupled to the CPU 192 and the memory 194 can be non-transitory computer readable storage medium and may be one or more of readily available memory such as random access memory (RAM), read only memory (ROM), floppy disk drive, hard disk, or any other form of digital storage, local or remote. Support circuits 196 are coupled to the CPU 192 for supporting the processor in a conventional manner. Charged species generation, heating, and other processes are generally stored in the memory 194, typically as software routine. The software routine may also be stored and/or executed by a second CPU (not shown) that is remotely located from the processing chamber 100 being controlled by the CPU 192.

The memory 194 is in the form of computer-readable storage media that contains instructions, that when executed by the CPU 192, facilitates the operation of the processing chamber 100. The instructions in the memory 194 are in the form of a program product such as a program that implements the method of the present disclosure. The program code may conform to any one of a number of different programming languages. In one example, the disclosure may be implemented as a program product stored on a computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such non-transitory computer-readable storage media, when carrying computer-readable instructions that direct the functions of the methods described herein, are embodiments of the present disclosure.

The inventors have discovered to ensure that little or no precursor residue remains on the gas distribution plate 138 after one or more processes have been performed, the gas distribution plate 138 can be maintained at a sufficiently high temperature. To achieve such a high temperature, the gas distribution plate 138 is heated from below by the heater 181 such that a temperature of the gas distribution plate 138 is maintained at a predetermined temperature greater than about 400° C. during a cleaning process. In some embodiments, the gas distribution plate can be maintained at a predetermined temperature from about 400° C. to about 450° C. during a cleaning process.

With reference to FIG. 2, a method 200 for cleaning a showerhead (e.g., the showerhead 150) disposed within a processing chamber (e.g., the processing chamber 100) is now herein described. For example, in at least some embodiments, the method 200 can be used to remove residue accumulated on the showerhead (e.g., the gas distribution plate 138) after multiple processes have been performed, e.g., about 3000 substrates to about 4000 substrates. For example, in at least some embodiments, the processing chamber can be configured to perform one or more CVD processes on a substrate e.g., a CVD tungsten (W) process, such as a seam-suppressed tungsten (SSW) process. The substrate can be formed from titanium chloride (TiCl), titanium nitride (TiN), or other material suitable for such CVD processes. Additionally, during such processes, residue including, but not limited to, boron (B), titanium (Ti), titanium fluoride (TiFₓ), tungsten (W), and the like can accumulate on the showerhead due to, for example, outgassing for an incoming substrate.

Accordingly, at 202 a substrate support including a heater (e.g., the heater 181) disposed therein is moved from a substrate processing position a first distance away from a showerhead to a cleaning position a second distance away from the showerhead, wherein the second distance is less than the first distance. For example, in at least some embodiments, a lift mechanism (e.g., the lift mechanism 182) can be used to move the support member from a substrate support incoming/outgoing/processing position to the cleaning position, which can be from about 350 mil to about 1000 mil from the showerhead.

Next, at 204 the showerhead can be heated using the heater disposed in the substrate support to a predetermined temperature. For example, in at least some embodiments, the heater can heat showerhead from about 210° C. to about 300° C., and in some embodiments, to about 230° C.

Next, at 206 at least one cleaning gas can be supplied to the processing chamber (e.g., to the plasma cavity 130 of the processing chamber). For example, the gas supply 135 can supply the at least one cleaning gas, which can include argon (Ar), fluorine (F), helium (He), nitrogen (N₂), and/or nitrogen trifluoride (NF₃). In at least some embodiments, the gas supply 135 can supply NF₃ and Ar to the processing chamber Once the cleaning gas is supplied to the plasma cavity 130, the power source 132 can ignite the cleaning gas to form a plasma, which can then be provided into the inner volume of the processing chamber via the gas distribution plate of the showerhead. For example, in at least some embodiments, the Ar can first be ignited to form Ar plasma, which can facilitate igniting the NF₃ to form NF₃ plasma. Thereafter, the Ar and NF₃ plasma can be used for cleaning the showerhead, as described below.

Alternatively or additionally, the plasma can be created remotely using, for example, the RPS 137. For example, the plasma can be created from the aforementioned at least one cleaning gas by the RPS 137, and the ions and radicals from the plasma be directed to the processing chamber, which can then be provided into the inner volume of the processing chamber via the gas distribution plate of the showerhead.

Next, at 208 a predetermined pressure is provided in the inner volume of the processing chamber. For example, in at least some embodiments, the pump 122 via the valve 124 can provide a pressure in the inner volume of the processing chamber from about 50 Torr to about 300 Torr. In at least some embodiments, the pressure within the inner volume of the processing chamber can be maintained (e.g., kept constant pressure) while heating the showerhead to the predetermined temperature and maintaining plasma within the inner volume of the processing chamber.

Under the conditions provided from 200-208, the plasma reacts with the gas distribution plate to remove the reside accumulated thereon. The process can be maintained or repeated for a duration suitable to remove all or substantially all of the residue disposed on the gas distribution plate, for example as described in more detail below.

Additionally, the gas supply 135 can supply at least one gas to facilitate heating the showerhead. For example, in at least some embodiments, hydrogen (H₂) can be supplied to the inner volume of the processing chamber while the showerhead is being heated. In such embodiments, the H₂ can be supplied from about 4000 sccm to about 8000 sccm.

In at least some embodiments, after 208, the inner volume of the processing chamber can be purged to remove spent gas, plasma, and/or removed residue (e.g., sublimated residue) from the inner volume of the processing chamber. For example, in at least some embodiments, the pump 122 via the valve 124 can purge the removed residue from the inner volume of the processing chamber to ensure the removed residue does no condensate on cold surfaces inside the processing chamber. For example, in at least some embodiments the inner volume of the processing chamber can be purged for about 10-20 seconds (e.g., corresponding to about 50 Torr to 300 Torr). In embodiments where the RPS 137 is used to provide the plasma to the processing chamber, the purging process can also include purging the RPS.

Additionally, in at least some embodiments, the showerhead can be heated to a temperature from about 25° C. to about 65° C. above the predetermined temperature using, for example, a heater or other device suitable for heating the showerhead. For example, a heat exchanger 141 (e.g., including one or more fluid channels containing a heating fluid) can be disposed in an area of the process chamber suitable for transferring heat to the showerhead. For example, in at least some embodiments, the heat exchanger 141 can be disposed within walls of the process chamber and configured to heat the showerhead. For example, in at least some embodiments, the heat exchanger 141 can be disposed in the lid rim 142, which as noted above, can function as a temperature control ring, e.g., to heat the showerhead. Alternatively or additionally, the heat exchanger 141 can be disposed in one or more components of the lid assembly 104, e.g., the second electrode 128. Alternatively or additionally, in at least some embodiments, one or more resistive heating elements (not shown) can be disposed in the inner volume of the processing chamber, e.g., embedded in the showerhead (e.g., in the gas distribution plate 138) or adjacent to the showerhead, and can be configured to heat the showerhead to a temperature from about 25° C. to about 65° C. above the predetermined temperature.

As noted above, the methods and apparatus described herein can clean a showerhead in about 10 hours to about 12 hours, while the processing chamber door remains closed.

202-208 can be performed one or more times to complete a cleaning cycle, depending on MWBC. In at least some embodiments, for example, a cleaning cycle can include performing 202-208 multiple times. For example, in at least some embodiments, 202-208 can be performed 2, 3, 4, 5, 6, . . . times followed by performing a purge of the processing chamber and/or the RPS, which can be performed multiple 2, 3, 4, 5, 6, . . . times prior to performing 202-208 again.

While the foregoing is directed to embodiments of the present disclosure, other and further embodiments of the disclosure may be devised without departing from the basic scope thereof.

1. A method for cleaning a showerhead in a processing chamber, comprising:
moving a substrate support including a heater disposed therein from a substrate processing position a first distance away from the showerhead to a cleaning position a second distance away from the showerhead, wherein the second distance is less than the first distance;
heating the showerhead using the heater disposed in the substrate support to a predetermined temperature;
at least one of supplying at least one cleaning gas to the processing chamber to form a plasma or supplying the plasma from a remote plasma source; and
providing a predetermined pressure within an inner volume of the processing chamber and maintaining the plasma within the inner volume of the processing chamber while heating the showerhead to the predetermined temperature.

2. The method of claim 1, further comprising, after maintaining the predetermined pressure and the plasma within the inner volume of the processing chamber while heating the showerhead to the predetermined temperature, purging the inner volume of the processing chamber for about 10 seconds to about 20 seconds.

3. The method of claim 1, wherein moving the substrate support to the cleaning position comprises positioning the substrate support from about 350 mil to about 1000 mil from the showerhead.

4. The method of claim 1, wherein further comprising supplying at least one gas from about 4000 sccm to about 8000 sccm to facilitate heating the showerhead.

5. The method of claim 1, wherein the plasma is formed using at least one of argon (Ar), fluorine (F), helium (He), nitrogen (N₂), or NF₃.

6. The method of claim 1, wherein the showerhead is heated from about 210° C. to about 300° C., and wherein the predetermined pressure within the inner volume of the processing chamber is about 50 Torr to about 300 Torr.

7. The method of claim 1, further comprising heating the showerhead to temperature from about 25° C. to about 65° C. above the predetermined temperature using a heat exchanger of the processing chamber.

8. A non-transitory computer readable storage medium having stored thereon instructions that when executed by a processor perform a method for cleaning a showerhead disposed in a processing chamber, the method comprising:
moving a substrate support including a heater disposed therein from a substrate processing position a first distance away from the showerhead to a cleaning position a second distance away from the showerhead, wherein the second distance is less than the first distance;
heating the showerhead using the heater disposed in the substrate support to a predetermined temperature;
at least one of supplying at least one cleaning gas to the processing chamber to form a plasma or supplying the plasma from a remote plasma source; and
providing a predetermined pressure within an inner volume of the processing chamber and maintaining the plasma within the inner volume of the processing chamber while heating the showerhead to the predetermined temperature.

9. The non-transitory computer readable storage medium of claim 8, further comprising, after maintaining the predetermined pressure and the plasma within the inner volume of the processing chamber while heating the showerhead to the predetermined temperature, purging the inner volume of the processing chamber for about 10 seconds to about 20 seconds.

10. The non-transitory computer readable storage medium of claim 8, wherein moving the substrate support to the cleaning position comprises positioning the substrate support from about 350 mil to about 1000 mil from the showerhead.

11. The non-transitory computer readable storage medium of claim 8, further comprising supplying at least one gas from about 4000 sccm to about 8000 sccm to facilitate heating the showerhead.

12. The non-transitory computer readable storage medium of claim 8, wherein the plasma is formed using at least one of argon (Ar), fluorine (F), helium (He), nitrogen (N₂), or NF₃.

13. The non-transitory computer readable storage medium of claim 8, wherein the showerhead is heated from about 210° C. to about 300° C., and wherein the predetermined pressure within the inner volume of the processing chamber is about 50 Torr to about 300 Torr.

14. The non-transitory computer readable storage medium of claim 8, further comprising heating the showerhead to temperature from about 25° C. to about 65° C. above the predetermined temperature using a heat exchanger of the processing chamber.

15. A processing chamber, comprising:
a substrate support movable from a substrate processing position a first distance away from a showerhead to a cleaning position a second distance away from the showerhead, wherein the second distance is less than the first distance;
at least one of a gas supply that supplies at least one cleaning gas to the processing chamber to form a plasma or a remote plasma source configured to supply the plasma to the processing chamber;
a heater disposed in the substrate support to heat the showerhead to a predetermined temperature;
a pressure system that provides a predetermined pressure within an inner volume of the processing chamber while the plasma is maintained within the inner volume of the processing chamber and the showerhead is being heated to the predetermined temperature; and
a controller configured to control the processing chamber to:
move the substrate support including the heater disposed therein from the substrate processing position the first distance away from the showerhead to the cleaning position the second distance away from the showerhead, wherein the second distance is less than the first distance;
heat the showerhead using the heater disposed in the substrate support to the predetermined temperature;
at least one of supply at least one cleaning gas to the processing chamber to form the plasma or supply the plasma from the remote plasma source; and
provide the predetermined pressure within the inner volume of the processing chamber and maintain the plasma within the inner volume of the processing chamber while heating the showerhead to the predetermined temperature.

16. The processing chamber of claim 15, wherein the controller is further configured to control the processing chamber to, after maintaining the predetermined pressure and the plasma within the inner volume of the processing chamber while heating the showerhead to the predetermined temperature, purge the inner volume of the processing chamber for about 10 seconds to about 20 seconds.

17. The processing chamber of claim 15, wherein the substrate support is configured to position the heater from about 350 mil to about 1000 mil from the showerhead.

18. The processing chamber of claim 15, wherein the at least one cleaning gas comprises is at least one of argon (Ar), fluorine (F), helium (He), nitrogen (N₂), or NF₃.

19. The processing chamber of claim 15, wherein the heater is configured to heat the showerhead from about 210° C. to about 300° C., and wherein the pressure system is configured to provide the predetermined pressure from about 50 Torr to about 300 Torr.

20. The processing chamber of claim 15, further comprising a heat exchanger configured to heat the showerhead to a temperature from about 25° C. to about 65° C. above the predetermined temperature.
